(19) United States
(12) Patent Application Publication
(10) Pub. No.: US 2024/0355964 A1
(43) Pub. Date: Oct. 24, 2024

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: Jenlung YANG, Xiamen (CN); Ping ZHANG, Xiamen (CN); Yawen LIN, Xiamen (CN); Shiwang HUANG, Xiamen (CN); Chung-Ying CHANG, Xiamen (CN)

(21) Appl. No.: 18/624,467

(22) Filed: Apr. 2, 2024

(30) Foreign Application Priority Data
Apr. 20, 2023 (CN) 2023104270899

(51) Int. Cl. H01L 33/14; H01L 33/06; H01L 33/32; H01L 33/62

(52) U.S. Cl. CPC H01L 33/145; H01L 33/06; H01L 33/32; H01L 33/62

(57) ABSTRACT

A light-emitting diode includes a current-blocking layer disposed on a second semiconductor layer of a semiconductor stacking layer and including a strip-shaped part, a transparent conducting layer disposed on the second semiconductor layer and covering the current-blocking layer, a first electrode disposed on a first semiconductor layer of the semiconductor stacking layer, and a second electrode disposed on the transparent conducting layer and including a second electrode pad and a second electrode extension part. As viewed from a top of the light-emitting diode towards the semiconductor stacking layer, a first side of the strip-shaped part defines a first distance from a side of the second electrode extension part facing towards the first side, and a second side of the strip-shaped part defines a second distance from a side of the second electrode extension part facing towards the second side, and the first distance is greater than the second distance.

### TECHNICAL FIELD

The disclosure relates to the technical field of semiconductor manufacturing, and particularly to a light-emitting diode (LED) and a light-emitting device.

### BACKGROUND

LED is a semiconductor light-emitting element and is usually made of a semiconductor such as gallium nitride (GaN), gallium arsenide (GaAs), gallium phosphide (GaP), or gallium arsenide phosphide (GaAsP), and its core is a positive-negative (PN) junction with light-emitting properties. LED is considered one of the most promising light sources due to its high light-emitting intensity, high efficiency, small size, and long service life. LED has been widely used in lighting, monitoring and command, high-definition broadcasting, high-end cinemas, office displays, conference interaction, virtual reality and other fields.

At present, in the LED industry, in order to achieve effective current expansion, multiple extended electrode designs are generally adopted. However, due to differences in field intensity (also referred to as intensity of electric field) and current density corresponding to different areas of the chip (i.e., LED chip), it is still inevitable that some areas will have relatively concentrated current density. Therefore, how to further optimize the design of current-blocking layers and improve the light-emitting efficiency of LED chips is a technical challenge that those skilled in the art need to solve.

### SUMMARY

A LED is provided to solve technical problems in the background and achieves effective current expansion. In some embodiments, the LED includes a semiconductor stacking layer, a current-blocking layer, a transparent conducting layer, a first electrode, and a second electrode. The semiconductor stacking layer includes a first semiconductor layer, a light-emitting layer and a second semiconductor layer, and the light-emitting layer is disposed between the first semiconductor layer and the second semiconductor layer. The current-blocking layer is disposed on the second semiconductor layer and includes at least one strip-shaped part. The transparent conducting layer is disposed on the second semiconductor layer and covers the current-blocking layer. The first electrode is disposed on the first semiconductor layer. The second electrode is disposed on the transparent conducting layer and includes a second electrode pad (i.e., pad of the second electrode) and at least one second electrode extension part (i.e., extension part of the second electrode), the second electrode pad is connected to the at least one second electrode extension part, and the at least one second electrode extension part is disposed on the at least one strip-shaped part. As viewed from a top of the LED towards the semiconductor stacking layer, each strip-shaped part includes: a first side and a second side; the first side of each strip-shaped part defines a first distance from a side of a respective one of the at least one second electrode extension part facing towards the first side (i.e., the first side and this side of the respective second electrode extension part are on a same side of the respective second electrode extension part); and the second side of each strip-shaped part defines a second distance from a side of the respective second electrode extension part facing towards the second side (i.e., the second side and the side of the respective second electrode extension part are on a same side of the respective second electrode extension part); and the first distance of one of the at least one strip-shaped part is greater than the second distance of the one strip-shaped part.

Another LED is provided. In some embodiment, the LED includes a semiconductor stacking layer, a current-blocking layer, a transparent conducting layer, a first electrode, and a second electrode. The semiconductor stacking layer includes a first semiconductor layer, a light-emitting layer and a second semiconductor layer, and the light-emitting layer is disposed between the first semiconductor layer and the second semiconductor layer. The current-blocking layer is disposed on the second semiconductor layer and includes at least one strip-shaped part. The transparent conducting layer is disposed on the second semiconductor layer and covers the current-blocking layer. The first electrode is disposed on the first semiconductor layer. The second electrode is disposed on the transparent conducting layer and includes a second electrode pad and at least one second electrode extension part, the second electrode pad is connected to the at least one second electrode extension part, and the at least one second electrode extension part is disposed on the at least one strip-shaped part. As viewed from a cross-sectional view where the at least one strip-shaped part is located, a projection of one of the at least one strip-shaped part of the current-blocking layer on the second semiconductor layer defines two mesas of a first mesa and a second mesa non-overlapped with the at least one second electrode extension part; a projection of the first mesa and a projection of second mesa on the second semiconductor layer are located on different sides of the one strip-shaped part of the current-blocking layer, respectively, and the first mesa is greater than the second mesa.

A light-emitting device adopting the LED mentioned above is also provided.

The LED and the light-emitting device are provided. Based on the differences in field intensity and current density corresponding to different areas of a chip, a current-blocking layer with unequal distance expansion is designed to achieve control of local current effect. Specifically, the current-blocking layer has different width distances on two sides of the same extended electrode, or the current-blocking layer has different width distances on extended electrodes in different areas, so as to avoid the phenomenon of relatively concentrated current density in certain areas, thereby improving the emitting-light efficiency and reliability of the LED chip (i.e., LED), and further enhancing the photoelectric performance of the LED.

The other features and beneficial effects of the disclosure will be described in the subsequent specification, and will be partially apparent from the specification or understood through the embodiments of the disclosure.

### BRIEF DESCRIPTION OF DRAWINGS

In order to provide a clearer explanation of the embodiments of the disclosure or the technical solutions in the related art, a brief introduction will be made to the attached drawings required in the embodiments or description of the related art. It is apparent that the attached drawings in the following description are some of the embodiments of the disclosure. For those skilled in the art, other attached drawings can be obtained based on these drawings without creative labor.

FIG. 1 illustrates a top view of a LED according to an embodiment 1 of the disclosure.

FIG. 2 illustrates a schematic enlarged structural view of a portion A of the LED illustrated in FIG. 1 according to the embodiment 1 of the disclosure.

FIG. 3 illustrates a first schematic enlarged structural view of a portion B of the LED illustrated in FIG. 1 according to the embodiment 1 of the disclosure.

FIG. 4 illustrates a second schematic enlarged structural view of the portion B of the LED illustrated in FIG. 1 according to the embodiment 1 of the disclosure.

FIG. 5 illustrates a third schematic enlarged structural view of the portion B of the LED illustrated in FIG. 1 according to the embodiment 1 of the disclosure.

FIG. 6 illustrates a cross-sectional view of the LED according to the embodiment 1 of the disclosure.

FIG. 7 illustrates a top view of a LED according to an embodiment 2 of the disclosure.

FIG. 8 illustrates a top view of a LED according to an embodiment 3 of the disclosure.

FIG. 9 illustrates a top view of a LED according to an embodiment 4 of the disclosure.

FIG. 10 illustrates a top view of a LED according to an embodiment 5 of the disclosure.

FIG. 11 illustrates a top view of a LED according to an embodiment 6 of the disclosure.

FIG. 12 illustrates a cross-sectional view of a LED according to an embodiment 7 of the disclosure.

FIG. 13 illustrates a top view of a LED according to the embodiment 7 of the disclosure.

FIG. 14 illustrates a cross-sectional view of a LED according to an embodiment 8 of the disclosure.

### DESCRIPTION OF REFERENCE NUMERALS

10. substrate; 12. semiconductor stacking layer; 123. first semiconductor layer; 124. light-emitting layer; 125. second semiconductor layer; 14. current-blocking layer; 141. main body part; 142. strip-shaped part; 1421. central strip-shaped part; 1422. edge strip-shaped part; 21. first electrode; 211. first electrode pad; 212. first electrode extension part; 22. second electrode; 221. second electrode pad; 222. second electrode extension part; 31. first side; 32. second side; L1, L1′, L1″. first distance; L2, L2′, L2″. second distance; 16. transparent conducting layer; 18. insulating layer; 41. first bonding pad; 42. second bonding pad; 61. second current-blocking layer; 51. opening; 15. interconnected electrode; M1. first mesa; M2. second mesa.

### DETAILED DESCRIPTION OF EMBODIMENTS

In order to clarify the purpose, technical solution, and advantages of the embodiments of the disclosure, the following will provide a clear and complete description of the technical solution in the embodiments of the disclosure in conjunction with the attached drawings. Apparently, the described embodiments are a part of the embodiments of the disclosure, not all of them. The technical features designed in different embodiments of the disclosure described below can be combined with each other as long as they do not conflict with each other. Based on the embodiments in the disclosure, all other embodiments obtained by those skilled in the art without creative labor fall within the scope of protection of the disclosure.

In the description of the disclosure, it should be understood that the terms “center”, “horizontal”, “up”, “down”, “left”, “right”, “vertical”, “horizontal”, “top”, “bottom”, “inside”, and “outside” indicate that the orientation or position relationship is based on the orientation or position relationship shown in the attached drawings, only for the convenience of describing the disclosure and simplifying the description, rather than indicating or implying that the device or component referred to must have a specific orientation, or be constructed and operated in a specific orientation, it cannot be understood as a limitation of the disclosure. In addition, the terms “first” and “second” are only used to describe the purpose and cannot be understood as indicating or implying relative importance or implying the quantity of technical features indicated. Therefore, the features limited to “first” and “second” can explicitly or implicitly include one or more of these features. In the description of the disclosure, unless otherwise specified, “multiple” means two or more. In addition, the term “including” and any variations thereof mean “at least including”.

A LED is provided to solve technical problems in the background and achieve effective current expansion. In some embodiments, the LED includes a semiconductor stacking layer, a current-blocking layer, a transparent conducting layer, a first electrode, and a second electrode.

The semiconductor stacking layer includes a first semiconductor layer, a light-emitting layer and a second semiconductor layer, and the light-emitting layer is disposed between the first semiconductor layer and the second semiconductor layer.

The current-blocking layer is disposed on the second semiconductor layer and includes at least one strip-shaped part.

The transparent conducting layer is disposed on the second semiconductor layer and covers the current-blocking layer.

The first electrode is disposed on the first semiconductor layer. The second electrode is disposed on the transparent conducting layer and includes a second electrode pad and at least one second electrode extension part, the second electrode pad is connected to the at least one second electrode extension part, and the at least one second electrode extension part is disposed on the at least one strip-shaped part.

As viewed from a top of the LED towards the semiconductor stacking layer, each strip-shaped part includes: a first side and a second side; the first side of each strip-shaped part defines a first distance from a side of a respective one of the at least one second electrode extension part facing towards the first side (i.e., the first side and this side of the respective second electrode extension part are on a same side of the respective second electrode extension part), and the second side of each strip-shaped part defines a second distance from a side of the respective second electrode extension part facing towards the second side (i.e., the second side and the side of the respective second electrode extension part are on a same side of the respective second electrode extension part); and the first distance of one of the at least one strip-shaped part is greater than the second distance of the one strip-shaped part. Based on the differences in field intensity and current density corresponding to different areas of a chip, the current-blocking layer with different widths is disposed on two sides of the same extended electrode to avoid the phenomenon of relatively concentrated current density in certain areas, thereby improving the light-emitting efficiency and reliability of the LED chip, and further enhancing the photoelectric performance of the LED.

In some embodiments, the first distance is a shortest distance of the first side of the strip-shaped part from the side of the respective second electrode extension part facing towards the first side, and the second distance of the strip-shaped part is a shortest distance of the second side of the strip-shaped part from the side of the respective second electrode extension part facing towards the second side.

In some embodiments, a width of each strip-shaped part is greater than a width of the respective second electrode extension part. Furthermore, in a top view, a projection of the second electrode extension part is located in the respective strip-shaped part. Specifically, when the width of the current-blocking layer is longer, the current near the electrode extension part can be more significantly diffused around the chip, thereby achieving local current regulation, maximizing the utilization of the light-emitting area and improving the light-emitting efficiency and utilization of the light-emitting area of the chip.

In some embodiments, the first distance of each strip-shaped part is in a range of 1-15 micrometers (μm), and the second distance of each strip-shaped part is in a range of 1-15 μm. When the area of the current-blocking layer is too large, it will lead to the ineffective utilization of the light-emitting area at the bottom of the current-blocking layer, resulting in a decrease in the overall light-emitting effect. When the area of the current-blocking layer is too small, it will not be able to block the current flowing vertically from the upper electrode into the second semiconductor layer, which will not have the effect of regulating current accumulation.

Preferably, in some embodiments, the first distance is in a range of 0.5-5 μm longer than the second distance. Preferably, in some embodiments, the second distance is in a range of ¼-¾ to the first distance. These relationship between the first distance and the second distance can ensure that different current regulation effects can be effectively applied on two sides of the same extended electrode, and the current density in different areas of the chip can be adjusted.

Preferably, in some embodiments, a number of the at least one strip-shaped part is same as a number of the at least one second electrode extension part.

In some embodiments, as viewed from the top of the LED towards the semiconductor stacking layer, the first side of the one of the at least one strip-shaped part is closer to the first electrode than the second side of the one of the at least one strip-shaped part. A wider current-blocking layer is disposed on the side of the same extended electrode closer to the first electrode, so as to avoid the phenomenon of relatively concentrated current density in the area closer to the first electrode, thereby improving the light-emitting efficiency and anti-static impact resistance of the LED chip.

In some embodiments, as viewed from the top of the LED towards the semiconductor stacking layer, the at least one strip-shaped part includes a central strip-shaped part and multiple edge strip-shaped parts. Preferably, in some embodiments, a first side is closer to the central strip-shaped part than a second side in each edge strip-shaped part; and a first distance is equal to a second distance in the central strip-shaped part, and a first distance is greater than a second distance in each edge strip-shaped part. The wider current-blocking layer is disposed on the extended electrode near the central area of the LED, so as to achieve the more significant blocking effect near the central area of the LED, thereby improving the light-emitting efficiency of the chip to a certain extent.

In some embodiments, the first distance or the second distance of the central strip-shaped part is in a range of 1-15 μm, and the first distance and the second distance of each edge strip-shaped part are in a range of 1-15 μm. An appropriate area of the current-blocking layer can achieve the effect of regulating current accumulation and ensure the effective utilization of the light-emitting area.

Preferably, in some embodiments, the first distance is in a range of 0.5-5 μm longer than the second distance in the one of the multiple edge strip-shaped part. Preferably, in some embodiments, the second distance is in a range of ¼-¾ to the first distance in the one of the multiple edge strip-shaped part. Therefore, sufficient and effective implementation of regulating the current density in different areas of the chip can be ensured.

Another LED is also provided and includes a semiconductor stacking layer, a current-blocking layer, a transparent conducting layer, a first electrode, and a second electrode.

The semiconductor stacking layer includes: a first semiconductor layer, a light-emitting layer and a second semiconductor layer, and the light-emitting layer is disposed between the first semiconductor layer and the second semiconductor layer.

The current-blocking layer is disposed on the second semiconductor layer and includes at least one strip-shaped part.

The transparent conducting layer is disposed on the second semiconductor layer and covers the current-blocking layer.

The first electrode is disposed on the first semiconductor layer. The second electrode is disposed on the transparent conducting layer and includes a second electrode pad and at least one second electrode extension part, the second electrode pad is connected to the at least one second electrode extension part, and the at least one second electrode extension part is disposed on the at least one strip-shaped part.

As viewed from a cross-sectional view where the at least one strip-shaped part is located, a projection of one of the at least one strip-shaped part of the current-blocking layer on the second semiconductor layer defines two mesas of a first mesa and a second mesa non-overlapped with the at least one second electrode extension part; a projection of the first mesa and a projection of second mesa on the second semiconductor layer are located on different sides of the one strip-shaped part of the current-blocking layer, respectively, and the first mesa is greater than the second mesa. Based on the differences in field intensity and current density corresponding to different areas of the chip, the current-blocking layer with different sizes are disposed on different sides of the same extended electrode to achieve current regulation in local areas of the chip, thereby avoiding the phenomenon of relative concentration of current density in certain areas, thereby improving the light-emitting efficiency and anti-static impact ability of the LED chip, and further improving the optoelectronic performance of the LED.

Preferably, in some embodiments, the second mesa is in a range of ¼-¾ to the first mesa, which is to ensure sufficient and effective implementation of regulating the current density in different areas of the chip.

Preferably, in some embodiments, the first mesa is closer to the first electrode than the second mesa. The area of the side of the current-blocking layer close to a side of the first electrode is increased to avoid the phenomenon of relatively concentrated current density in the area closer to the first electrode, thereby achieving the effect of improving the light-emitting efficiency and anti-static impact resistance of the LED chip.

In some embodiments, the current-blocking layer is made of an insulating material configured to transmit at least partial light, and the insulating material includes one or more combinations of transparent inorganic insulating materials including silicon oxide (SiO₂), silicon nitride (Si₃N₄), nitride oxide silicon (Si₂N₂O), titanium oxide (TiO₂), magnesium oxide (MgO), and aluminum oxide (Al₂O₃).

In some embodiments, a thickness of the current-blocking layer is in a range of 50-500 nanometers (nm), which is to ensure effective blocking of the current flowing vertically from the upper electrode into the second semiconductor layer.

In some embodiments, the first electrode and the second electrode are made of metal materials, including at least one selected from the group consisting of nickel (Ni), gold (Au), chromium (Cr), titanium (Ti), platinum (Pt), palladium (Pd), rhodium (Rh), iridium (Ir), aluminum (Al), tin (Sn), indium (In), tantalum (Ta), copper (Cu), cobalt (Co), iron (Fe), ruthenium (Ru), zirconium (Zr), tungsten (W), and molybdenum (Mo), or at least one of alloys or laminated layers of the above metal materials.

In some embodiments, the first electrode includes a first electrode pad and a first electrode extension part, the first electrode pad is connected to the first electrode extension part, the first electrode extension part extends from the first electrode pad towards the second electrode, and the second electrode extension part extends from the second electrode pad towards the first electrode pad.

In some embodiments, the at least one second electrode extension part is in a strip-shaped structure or an annular structure, and the at least one strip-shaped part is in a strip-shaped structure or an annular structure corresponding to the at least one second electrode extension part of the second electrode.

In some embodiments, the at least one strip-shaped part of the current-blocking layer includes a strip-shaped part continuously distributed or strip-shaped parts intermittently distributed. In some embodiments, at least one opening is defined on the at least one strip-shaped part. The transparent conducting layer is connected to the second semiconductor layer through an intermittent part between the strip-shaped parts intermittently distributed or the opening, which can increase the contact between the transparent conducting layer and the second semiconductor layer, thereby improving the current expansion ability and enhancing the light-emitting efficiency of the LED chip.

Preferably, in some embodiments, a ratio of a length of the LED to a width of the LED is greater than 1. When the length-width ratio of the LED is large, the current expansion ability in the long side direction is poor. Based on the differences in field intensity and current density corresponding to different areas of the chip, the current-blocking layer with unequal distance expansion is disposed on two sides of the extended electrode to allow the current to conduct more in the long side direction of the chip, resulting in the more prominent light-emitting effect.

A light-emitting device, adopting the LED mentioned in any one of the above embodiments is further provided.

The following will provide a clear and complete description of the technical solution of the disclosure through various specific embodiments, in conjunction with the attached drawings in the embodiments of the disclosure.

### Embodiment 1

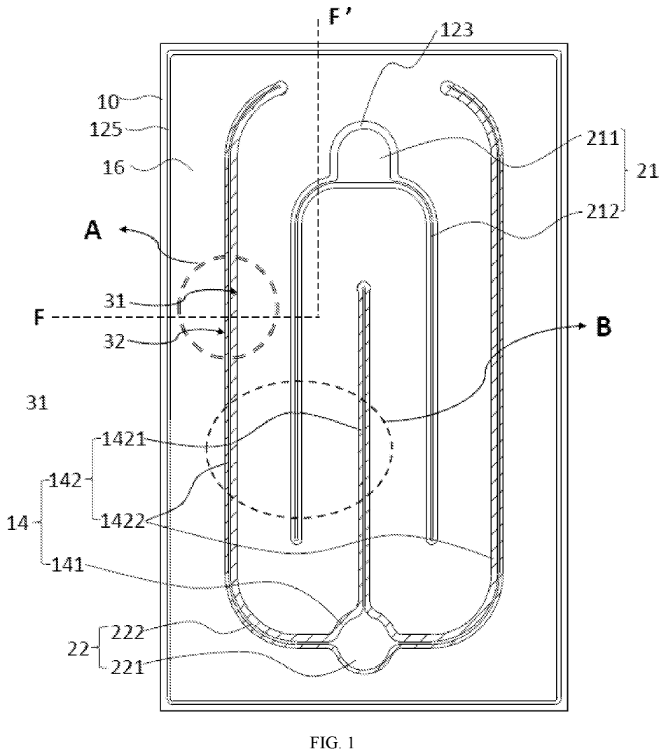

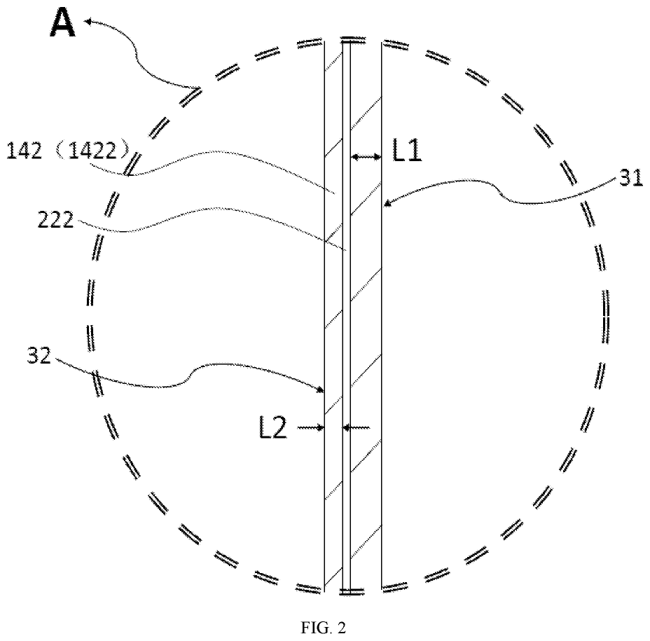

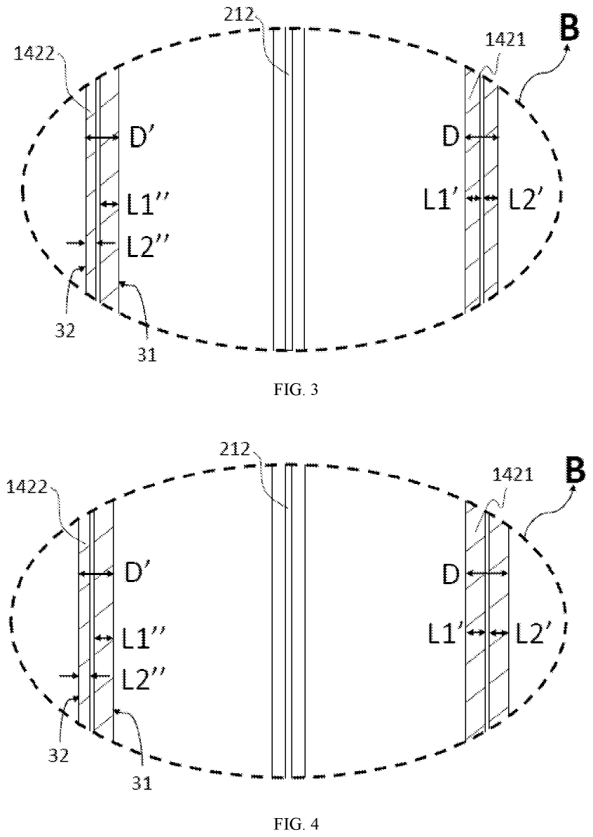

As shown in FIGS. 1 to 6, FIG. 1 illustrates a top view of a LED according to the embodiment 1. FIG. 2 illustrates a schematic enlarged structural view of a portion A (i.e., the area circled by a double dashed circle in FIG. 1) of the LED illustrated in FIG. 1 according to the embodiment 1. FIGS. 3-5 illustrate schematic enlarged structural views of a portion B (i.e., the area circled by a single dashed circle in FIG. 1) of the LED illustrated in FIG. 1, which respectively demonstrates several different designs of the current-blocking layer 14 with unequal distance expansion provided in the embodiment 1. FIG. 6 illustrates a cross-sectional view of the LED according to the embodiment 1, which is a schematic diagram of a longitudinal section taken along a F-F line of FIG. 1. The LED is provided and includes a semiconductor stacking layer 12, a current-blocking layer 14, a transparent conducting layer 16, a first electrode 21 and a second electrode 22. It should be noted that in order to clarify the shape of the current-blocking layer 14, the current-blocking layer 14 in the figures is shown in a fill pattern.

The semiconductor stacking layer 12 is disposed on the substrate 10. The substrate 10 can be an insulating substrate. Specifically, the substrate 10 is made of a transparent material or a semi-transparent material. In the embodiment, the substrate 10 is a sapphire substrate. In some embodiments, the substrate 10 may be a patterned sapphire substrate, but it is not limited to this. The substrate 10 can also be made of a conductive or semiconductor material. For example, the material of the substrate 10 may include at least one selected from the group consisting of silicon carbide (SiC), silicon, magnesium aluminum oxide (Al₂Mg₂O₅), magnesium oxide, lithium aluminum oxide (LiAlO₂), aluminum gallium oxide, and gallium nitride.

The semiconductor stacking layer 12 includes a first semiconductor layer 123, a light-emitting layer 124, and a second semiconductor layer 125. The light-emitting layer 124 is disposed between the first semiconductor layer 123 and the second semiconductor layer 125. A part of an upper surface of the first semiconductor layer 123 that is not covered by the light-emitting layer 124 forms mesas, and the mesas are mainly used for setting electrodes.

The first semiconductor layer 123 can be a negative-type (N-type) semiconductor layer, which can provide electrons to the light-emitting layer 124 under the action of a power source. In some embodiments, the first semiconductor layer 123 includes an N-type doped nitride layer. The N-type doped nitride layer may include N-type impurities of one or more group IV elements. The N-type impurities include one or more selected from the group consisting of silicon (Si), germanium (Ge) and tin (Sn). In some embodiments, a buffer layer can also be disposed between the N-type semiconductor layer and the substrate 10 to alleviate lattice mismatch between the substrate 10 and the N-type semiconductor layer. The buffer layer may include an un-doped aluminum nitride (u-AlN) layer or an un-doped aluminum gallium nitride (u-AlGaN) layer. The N-type semiconductor layer can also be connected to the substrate 10 through a bonding layer.

The light-emitting layer 124 can be a quantum well (QW) structure. In some embodiments, the light-emitting layer 124 can also be a multiple quantum well (MQW) structure, and the MQW structure includes multiple quantum well layers (Wells) and multiple quantum barrier layers (Barriers) alternately disposed in a repetitive manner, such as a GaN/AlGaN MQW structure, an indium aluminum gallium nitride (InAlGaN)/InAlGaN MQW structure, or a indium gallium nitride (InGaN)/AlGaN MQW structure. In addition, compositions and thicknesses of the quantum well layers inside the light-emitting layer 124 determine wavelengths of the generated light. In order to improve the light-emitting efficiency of the light-emitting layer 124, it can be achieved by changing a depth of the quantum well, the number of layers, thickness, and other characteristics of the paired quantum wells and quantum barriers in the light-emitting layer 124.

The second semiconductor layer 125 can be a positive type (P-type) semiconductor layer, which can provide holes to the light-emitting layer 124 under the action of a power source. In some embodiments, the second semiconductor layer 125 includes a P-type doped nitride layer. The P-type doped nitride layer may include P-type impurities of one or more group II elements. The P-type impurities can include one or a combination selected from the group consisting of magnesium (Mg), zinc (Zn), and beryllium (Be).

Although the first semiconductor layer 123 and the second semiconductor layer 125 can be single-layer structures, which is not limited to this. The first semiconductor layer 123 and the second semiconductor layer 125 can also be multi-layer structures, which have different compositions and can also include superlattice layers. In addition, the setting of the semiconductor stacking layer 12 is not limited to this, and other types of the semiconductor stacking layer 12 can be selected based on actual needs. For example, in other embodiments, in the case where the first semiconductor layer 123 is doped with the P-type impurities, the second semiconductor layer 125 can be doped with the N-type impurities, that is, the first semiconductor layer 123 is a P-type semiconductor layer, and the second semiconductor layer 125 is an N-type semiconductor layer. The current-blocking layer 14 can also be disposed below the first electrode 21, which is not limited to this.

The first electrode 21 is disposed on the first semiconductor layer 123. The first electrode 21 can be made of a metal material including at least one selected from the group consisting of nickel, gold, chromium, titanium, platinum, palladium, rhodium, iridium, aluminum, tin, indium, tantalum, copper, cobalt, iron, ruthenium, zirconium, tungsten, and molybdenum, or an alloy or a laminated layer of the above metal materials. The first electrode 21 can be a single-layer metal structure, a double-layer metal structure, or multi-layer metal structure, such as titanium/aluminum (Ti/Al), titanium/aluminum/titanium/gold (Ti/Al/Ti/Au), titanium/aluminum/nitride/gold (Ti/Al/Ni/Au), vanadium/aluminum/platinum/gold (V/Al/Pt/Au) and other metal layer structures. In some embodiments, the first electrode 21 can be directly formed on the mesa of the first semiconductor layer 123, thereby achieving a good ohmic contact with the first semiconductor layer 123. In some embodiments, the first electrode 21 may include a first electrode pad 211 and first electrode extension parts 212. The first electrode pad 211 is connected to the first electrode extension parts 212, and the first electrode extension parts 212 extend from the first electrode pad 211 towards the second electrode 22, which allows for uniform diffusion of the current. In the embodiment, the first electrode 21 includes a first electrode pad 211 and two first electrode extension parts 212, and the two first electrode extension parts 212 are in strip-shaped structures.

The second electrode 22 is disposed on the current-blocking layer 14. The second electrode 22 can be made of a metal material, which can be composed of the material that is the same or similar to the first electrode 21, and the second electrode 22 can also be composed of the material different from the first electrode 21. In some embodiments, the second electrode 22 includes a second electrode pad 221 and second electrode extension parts 222. The second electrode pad 221 is connected to the second electrode extension parts 222, and the second electrode extension parts 222 extend from the second electrode pad 221 towards the first electrode pad 211, which allows for uniform diffusion of the current. In the embodiment, the second electrode 22 includes a second electrode pad 221 and three second electrode extension parts 222, and the three second electrode extension parts 222 are in strip-shaped structures.

The current-blocking layer 14 is disposed on the second semiconductor layer 125 and is configured to block the current flowing vertically from the upper electrode (i.e., the second electrode) into the second semiconductor layer 125. As an example, the current-blocking layer 14 is made of an insulating material that can at least partially transmit light, and the insulating material includes one or more combinations of transparent inorganic insulating materials such as including silicon oxide, silicon nitride, silicon nitride, titanium oxide, magnesium oxide, and aluminum oxide. The current-blocking layer 14 can also be a single-layer structure or an alternating multi-layer structure, and the single-layer structure can be made of a material with a high transmittance, such as silicon oxide with a transmittance higher than 80%. The current-blocking layer 14 can also be made of a reflective material formed by a combination of multiple layers with a reflectivity higher than 60%, such as a Bragg reflector. The thickness of the current-blocking layer 14 can be selected from any thickness in a range of 50 nm and 500 nm, which is not limited to this.

The current-blocking layer 14 includes at least one strip-shaped part 142, and the second electrode extension part 222 is disposed on the strip-shaped part 142 of the current-blocking layer 14. Specifically, the number of the strip-shaped part 142 is the same as the number of the second electrode extension part 222, and they are arranged in a one-to-one correspondence. Moreover, each second electrode extension part 222 is disposed on a respective strip-shaped part 142. As shown in FIGS. 1 to 2, as viewed from a top of the LED towards the semiconductor stacking layer, each strip-shaped part 142 includes a first side 31 and a second side 32. The first side 31 of each strip-shaped part 142 defines a first distance L1 from a side of the respective second electrode extension part 222 facing towards the first side 31, and the second side 32 of each strip-shaped part 142 defines a second distance L2 from a side of the respective second electrode extension part 222 facing towards the second side 32, and the first distance L1 of one strip-shaped part 142 is greater than the second distance L2 of the one strip-shaped part 142. When the area of the LED is large, due to the poor current expansion ability, in order to avoid excessive current concentration, multiple extended electrode designs are generally adopted. However, even if the current is diffused as much as possible throughout the entire emitting area through the multiple extended electrodes, it is inevitable to occur the phenomenon of relatively concentrated current density in the certain areas. In order to further achieve effective current diffusion, the present design of the LED includes that a current-blocking layer with an equidistant distance expansion is disposed below the electrode pad and the electrode extension part extending from the electrode pad, and the shape and contour of the current-blocking layer are the same as the shape and contour of the electrode pad and the electrode extension part. However, due to differences in field intensity and current density in different areas of the chip, specifically, the difference in field intensity and current density on two sides of the same extended electrode cannot completely solve the existing technical problems by simply providing the current-blocking layer with the equidistant distance expansion. Therefore, the disclosure proposes to design the current-blocking layer 14 with unequal distance expansion on two sides of the same extended electrode, which can achieve the effect of local current regulation and avoid the phenomenon of relatively concentrated current density in certain areas, thereby improving the light-emitting efficiency and anti-static impact ability of the LED, and further enhancing the photoelectric performance of the LED.

In some embodiment, as viewed from a top of the LED towards the semiconductor stacking layer, the strip-shaped part 142 includes a central strip-shaped part 1421 and multiple edge strip-shaped parts 1422. The central strip-shaped part 1421 is disposed in a central area of the LED, and the multiple edge strip-shaped parts 1422 are disposed on a side or two sides of the central strip-shaped part 1421. The multiple edge strip-shaped parts 1422 are closer to the edge of the LED than the central strip-shaped part 1421. In the embodiment, as shown in FIG. 1, as viewed from a top of the LED towards the semiconductor stacking layer, the current-blocking layer 14 includes a main body part 141 and a strip-shaped part 142. The strip-shaped part 142 is continuously distributed, and the strip-shaped part 142 includes a central strip-shaped part 1421 and two edge strip-shaped parts 1422. The central strip-shaped part 1421 includes a first side 31 and a second side 32. The first side 31 of the central strip-shaped part 1421 defines a first distance L1′ from a side of the respective second electrode extension part 222 facing towards the first side 31, and the second side 32 of the central strip-shaped part 1421 defines a second distance L2′ from a side of the respective second electrode extension part 222 facing towards the second side 32. Specifically, the first distance L1′ of the central strip-shaped part 1421 is equal to the second distance L2′ of the central strip-shaped part 1421. Each edge strip-shaped part 1422 includes a first side 31 and a second side 32. The first side 31 of each edge strip-shaped part 1422 is closer to the central strip-shaped part 1421 than the second side 32 of each edge strip-shaped part 1422. The first side 31 of each edge strip-shaped part 1422 defines a first distance L1″ from a side of the respective second electrode extension part 222 facing towards the first side 31, the second side 32 of each edge strip-shaped part 1422 defines a second distance L2″ from a side of the respective second electrode extension part 222 facing towards the second side 32, and the first distance L1″ of each edge strip-shaped part 1422 is greater than the second distance L2″ of each edge strip-shaped part 1422.

In some embodiment, the first distance L1 of the strip-shaped part 142 is in a range of 1-15 micrometers (μm), the second distance L2 of the strip-shaped part 142 is in a range of 1-15 μm. Specifically, the first distance L1 of the strip-shaped part 142 is in a range of 5-12 μm, the second distance L2 of the strip-shaped part 142 is in a range of 3-10 μm, so as to avoid the excessive area of the current-blocking layer 14, which may result in the ineffective utilization of the light-emitting area at the bottom of the current-blocking layer, leading to a decrease in the overall light-emitting effect. Alternatively, it can be avoided that the area of the current-blocking layer 14 is too small, which is unable to block the current flowing vertically from the upper electrode into the second semiconductor layer 125, thereby failing to regulate current accumulation.

In some embodiments, the first distance L1 is in a range of 0.5-5 μm longer than the second distance L2. Specifically, the first distance L1 is in a range of 2-4 μm longer than the second distance L2. In some embodiments, the second distance L2 is in a range of ¼-¾ to the first distance L1. Specifically, the second distance L2 is in a range of ⅓-⅔ to the first distance L1, so as to ensure that different current regulation effects can be effectively applied on different sides of the same extended electrode, and the current density in different areas of the chip can be adjusted.

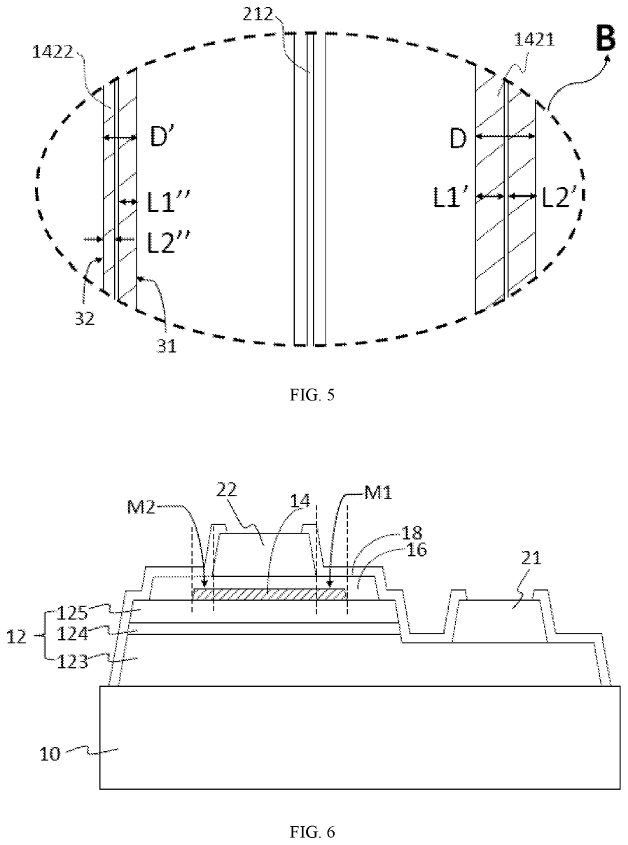

In some embodiments, the first distance L1′ and the second distance L2′ of the central strip-shaped part 1421 are in a range of 1-15 μm. The first distance L1″ of each edge strip-shaped part 1422 is in a range of 1-15 μm and the second distance L2″ of each edge strip-shaped part 1422 is in a range of 1-15 μm. In a specific embodiment, the first distance L1′ and the second distance L2′ of the central strip-shaped part 1421 are in a range of 5-12 μm, the first distance L1″ of each edge strip-shaped part 1422 is in a range of 5-12 μm, and the second distance L2″ of each edge strip-shaped part 1422 is in a range of 3-10 μm. In some embodiments, a width D of the central strip-shaped part 1421 and a width D′ of each edge strip-shaped part 1422 can be the same or different. The first distance L1′ or the second distance L2′ of the central strip-shaped part 1421 can be the same as or different from the first distance L1″ of the edge strip-shaped part 1422, and the first distance L1′ or the second distance L2′ of the central strip-shaped part 1421 can be greater than the first distance L1″ of the edge strip-shaped part 1422 or smaller than the first distance L1″ of the edge strip-shaped part 1422. This disclosure is not limited to this, as long as the first distance L1″ of the same edge strip-shaped part 1422 is greater than the second distance L2″ of the same edge strip-shaped part 1422, local current regulation effect can be achieved to improve the light-emitting efficiency and anti-static impact resistance of the LED. As shown in FIGS. 3 to 5, which respectively show different designs of the current-blocking layer 14 with unequal distance expansion in the embodiment. As shown in FIG. 3, the width D of the central strip-shaped part 1421 is equal to the width D′ of the edge strip-shaped part 1422. Therefore, the first distance L1′ or the second distance L2′ of the central strip-shaped part 1421 can be smaller than the first distance L1″ of the edge strip-shaped part 1422. For example, the first distance L1′ or the second distance L2′ of the central strip-shaped part 1421 is 7 μm, the first distance L1″ of the edge strip-shaped part 1422 is 9 μm, and the second distance L2″ of the edge strip-shaped part 1422 is 5 μm. As shown in FIG. 4, the first distance L1′ or second distance L2′ of the central strip-shaped part 1421 can be equal to the first distance L1″ of the edge strip-shaped part 1422. For example, the first distance L1′ or second distance L2′ of the central strip-shaped part 1421 is 7 μm, the first distance L1″ of the edge strip-shaped part 1422 is 7 μm, and the second distance L2″ of the edge strip 1422 is 5 μm. As shown in FIG. 5, the first distance L1′ or second distance L2′ of the central strip-shaped part 1421 can be greater than the first distance L1″ of the edge strip-shaped part 1422. For example, the first distance L1′ or second distance L2′ of the central strip-shaped part 1421 is 8 μm, the first distance L1″ of the edge strip-shaped part 1422 is 7 μm, and the second distance L2″ of the edge strip-shaped part 1422 is 5 μm. In addition, due to the relatively concentrated current density in the central area of the LED, the designs in FIGS. 4 and 5 can make the width D of the central strip-shaped part 1421 greater than the width D′ of the edge strip-shaped part 1422. In other words, the design of the extended electrode near the central area of the LED has a larger current-blocking layer 14, so as to achieve the more significant blocking effect near the central area of the LED, thereby improving the light-emitting efficiency of the chip to a certain extent.

In some embodiment, the first distance L1 is a shortest distance of the first side 31 of the strip-shaped part 142 from the side of the respective second electrode extension part 222 facing towards the first side 31, and the second distance L2 is a shortest distance of the second side 32 of the strip-shaped part 142 from the side of the respective second electrode extension part 222 facing towards the second side 32. In a specific embodiment, the first distance L1 or the second distance L2 from any point of the first side 31 or the second side 32 to the respective side of the second electrode extension part 222 is equal. The equality expressed here is understood in a broad sense (not exactly the same), for example, allowing for an error within 0.1 μm, such as the first distance L1 from a first point of the first side 31 to the side of the respective second electrode extension part 222 facing towards the first side 31 is 10 μm, and the first distance L1 from a second point of the first side 31 to the side of the respective second electrode extension part 222 facing towards the first side 31 is 10.1 μm, it is also the equivalent distance mentioned in this case.

In a specific embodiment, the width of the strip-shaped part 142 is greater than the width of the respective second electrode extension part 222. Specifically, in the top view, the projection of the second electrode extension part 222 is within the respective strip-shaped part 142. When the width of the current-blocking layer 14 is large, the current near the electrode extension part can be more significantly diffused around the chip. The current-blocking layer 14 with unequal distance expansion can be disposed on two sides of the same extended electrode to achieve local current control effect and maximize the utilization of the light-emitting area, thereby improving the light-emitting efficiency and the utilization rate of light-emitting area of the chip.

As shown in FIG. 6, FIG. 6 illustrates the cross-sectional view of the LED according to the embodiment 1, which is a schematic diagram of a longitudinal section taken along the F-F line of FIG. 1. Specifically, it is a schematic structural diagram of the cross-sectional structure of the area where the strip-shaped part 142 is located. From the cross-sectional view where the strip-shaped part 142 is located, the projection of the strip-shaped part 142 of the current-blocking layer 14 on the second semiconductor layer 125 defines two mesas of a first mesa M1 and a second mesa M2 non-overlapped with the second electrode extension parts 222. As shown in FIG. 6, a projection of the first mesa M1 and a projection of second mesa M2 on the second semiconductor layers 125 are located on different sides of the strip-shaped part 142 of the current-blocking layer 14, respectively, and the first mesa M1 is greater than the second mesa M2. By disposing the current-blocking layer 14 with different areas on different sides of the same extended electrode, current regulation in local areas of the chip is achieved, thereby avoiding the phenomenon of relatively concentrated current density in certain areas, improving the light-emitting efficiency and anti-static impact ability of the LED, and further enhancing the photoelectric performance of the LED.

In some embodiment, the second mesa M2 is in a range of ¼-¾ to the first mesa M1. In a specific embodiment, the second mesa is ⅓ to ⅔ of the first mesa, so as to ensure that different current regulation effects can be effectively applied on two sides of the same extended electrode, and the current density in different areas of the chip can be adjusted.

In some embodiment, the first mesa M1 is closer to the first electrode than the second mesa M2. By providing a larger current-blocking layer 14 on the side closer to the first electrode 21 on the same extended electrode, the phenomenon of relatively concentrated current density in the area closer to the first electrode 21 is avoided, further improving the light-emitting efficiency and anti-static impact resistance of the LED.

The transparent conducting layer 16 is disposed on the second semiconductor layer 125 and is used to guide current to be injected more uniformly from the upper electrode into the second semiconductor layer 125, thereby achieving the effect of current expansion. For example, the material of the transparent conducting layer 16 includes at least one selected from the group consisting of indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO) and zinc oxide (ZnO), but this is not limited to the embodiments. The transparent conducting layer 16 in this embodiment is an ITO layer.

An insulating layer 18 covers sidewalls and a part of an upper surface of the semiconductor stacking layer 12, the transparent conducting layer 16, the first electrode 21 and the second electrode 22. Openings are defined on the insulating layer 18, the first electrode 21 and the second electrode 22 are disposed in the openings of the insulating layer 18 for subsequent wire connections. The insulating layer 18 has different functions depending on the position of the insulating layer 18. For example, the part of the insulating layer 18 covering the sidewalls of the epitaxial layer is to prevent conductive material leakage to cause the first semiconductor layer 123 and the second semiconductor layer 125 to be electrically connected, thereby reducing short-circuit anomalies in the LED. However, this embodiment is not limited to this. In some embodiment, the material of the insulating layer 18 includes a non-conductive material. The non-conductive material is an inorganic material or a dielectric material. The inorganic material includes silicone or glass. The dielectric material includes aluminum oxide (AlO), silicon nitride (SiNₓ), silicon oxide (SiOₓ), titanium oxide (TiOₓ), or magnesium fluoride (MgFₓ). The material of the insulating layer 18 can be an electrical insulation material. For example, the material of the insulating layer 18 can be silicon dioxide, silicon nitride, titanium oxide, tantalum oxide, niobium oxide, barium titanate or a combination thereof, and the combination can be a Bragg reflector (DBR) formed by the repeated stacking of two materials.

### Embodiment 2

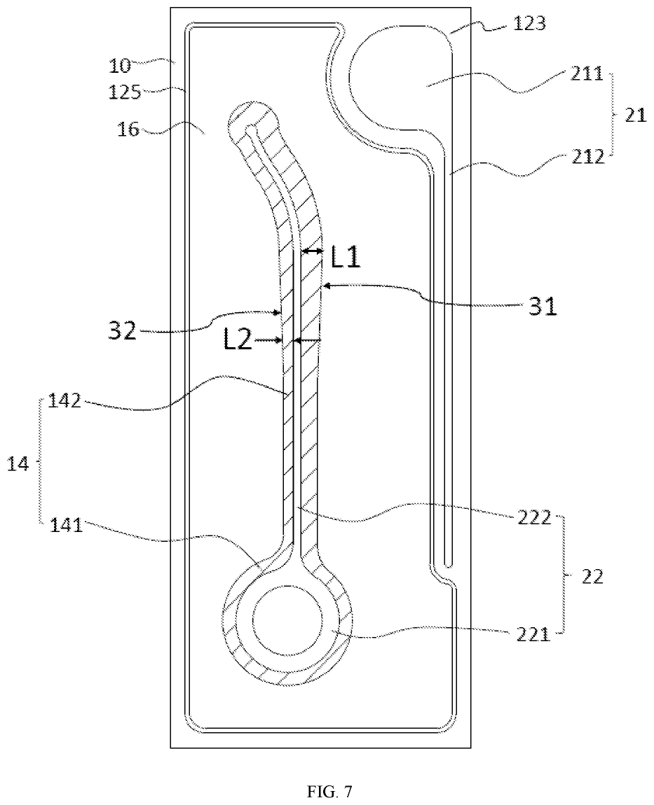

As shown in FIG. 7, which illustrates a top view of a LED according to the embodiment 2. Compared to the LED of the embodiment 1 in FIG. 1, the main differences of the LED of the embodiment 2 are as follows. The first electrode 21 includes a first electrode pad 211 and a first electrode extension part 212, and the second electrode 22 includes a second electrode pad 221 and a second electrode extension part 222. The current-blocking layer 14 includes a main body part 141 and a strip-shaped part 142, the second electrode extension part 222 is disposed on the strip-shaped part 142 of the current-blocking layer 14. The strip-shaped part 142 includes a first side 31 and a second side 32, as viewed from a top of the LED towards the semiconductor stacking layer, the first side 31 is closer to the first electrode 21 than the second side 32. The first side 31 defines a first distance L1 from a side of the second electrode extension part 222 facing towards the first side 31, and the second side 32 defines a second distance L2 from a side of the second electrode extension part 222 facing towards the second side 32, and the first distance L1 is greater than the second distance L2. In the embodiment, a side of the same strip-shaped part 142 closer to the first electrode 21 has a larger width or area, which has a more effective and obvious blocking effect. Preferably, the side of the same strip-shaped part 142 closer to the first electrode extension part 212 has a larger width or area, which has a more effective and obvious blocking effect. Because there is a relatively concentrated current density in the area where the second electrode 22 is closer to the first electrode 21 or first electrode extension part 212. Therefore, the design of the current-blocking layer 14 with a larger width or larger area on the side of the same extended electrode closer to the first electrode 21 or the first electrode extension part 212 is to avoid the phenomenon of relatively concentrated current density in the area closer to the first electrode 21 and to simultaneously improve the light-emitting efficiency and anti-static impact ability of the LED chips, thereby enhancing the optoelectronic performance of the LED.

### Embodiment 3

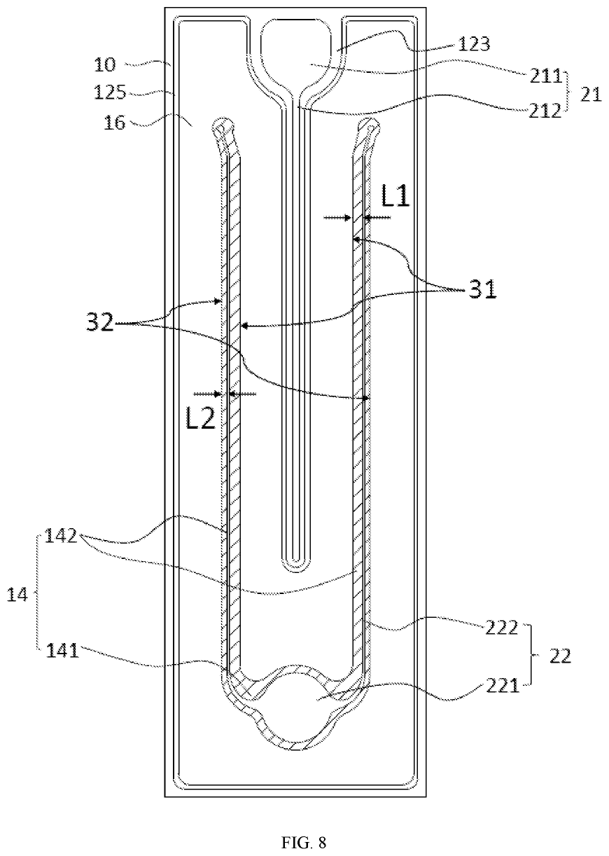

As shown in FIG. 8, which illustrates a top view of a LED according to the embodiment 3. Compared to the LED of the embodiment 1 in FIG. 1, the main differences of the LED of the embodiment 3 are as follows. The first electrode 21 includes a first electrode pad 211 and a first electrode extension part 212, and the second electrode 22 includes a second electrode pad 221 and two second electrode extension parts 222. The current-blocking layer 14 includes a main body part 141 and two strip-shaped parts 142, the two second electrode extension parts 222 are disposed on the two strip-shaped parts 142 of the current-blocking layer 14, respectively, and the distances between each strip-shaped part 142 and the central area of the LED chip is the same. Each strip-shaped part 142 includes a first side 31 and a second side 32, as viewed from a top of the LED towards the semiconductor stacking layer 12, the first side 31 of each strip-shaped part 142 is closer to the central area of the LED chip with relatively concentrated current density compared to the second side 32 of each strip-shaped part 142. The first side 31 of each strip-shaped part 142 defines a first distance L1 from a side of the second electrode extension part 222 facing towards the first side 31, and the second side 32 of each strip-shaped part 142 defines a second distance L2 from a side of the second electrode extension part 222 facing towards the second side 32. The first distance L1 is greater than the second distance L2, so as to improve the light-emitting efficiency and anti-static impact resistance of the LED chips, thereby enhancing the optoelectronic performance of LEDs.

### Embodiment 4

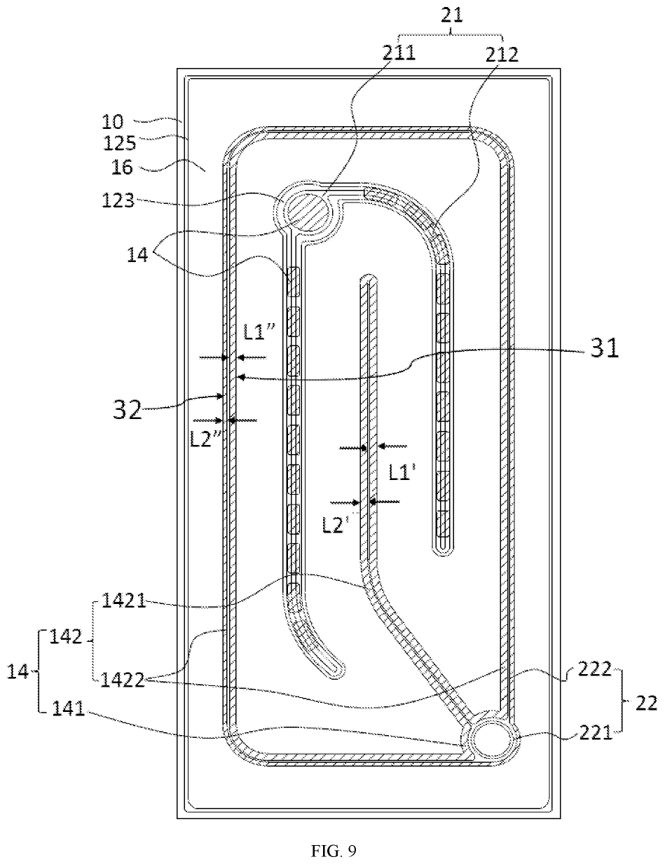

As shown in FIG. 9, which illustrates a top view of a LED according to the embodiment 4. Compared to the LED of the embodiment 1 in FIG. 1, the main differences of the LED of the embodiment 4 are as follows. The first electrode 21 includes a first electrode pad 211 and two first electrode extension parts 212, and the second electrode 22 includes a second electrode pad 221, a second electrode extension part 222 in a strip-shaped structure and a second electrode extension part 222 in an annular structure. The second electrode extension part 222 in the annular structure completely surrounds the first electrode 21. The current-blocking layer 14 includes a main body part 141 and a strip-shaped part 142, the strip-shaped part 142 includes a central strip-shaped part 1421 in the strip-shaped structure and an edge strip-shaped part 1422 in the annular structure, and the second electrode extension part 222 in the strip-shaped structure and the second electrode extension part 222 in the annular structure are disposed on the strip-shaped part 142. Specifically, the central strip-shaped part 1421 includes a first side 31 and a second side 32, the first side 31 of the central strip-shaped part 1421 defines a first distance L1′ from a side of the second electrode extension part in the strip-shaped structure 222 facing towards the first side 31 of the central strip-shaped part 1421, and the second side 32 of the central strip-shaped part 1421 defines a second distance L2′ from a side of the second electrode extension part in the strip-shaped structure 222 facing towards the second side 32 of the central strip-shaped part 1421, and the first distance L1′ is equal to the second distance L2′. The second electrode extension part 222 in the annular structure includes a first side 31 and a second side 32, the first side 31 and the second side 32 of the second electrode extension part 222 in the annular structure are both closed-loop, unlike FIG. 1 with a line segment. The first side 31 of the second electrode extension part 222 in the annular structure is closer to the central strip-shaped part 1421 than the second side 32 of the second electrode extension part 222 in the annular structure, that is, the first side 31 of the second electrode extension part 222 in the annular structure refers to an inner side of the current-blocking layer 14, and the second side 32 of the second electrode extension part 222 in the annular structure refers to an outer side of the current-blocking layer 14 (near an outer side of the LED). The first side 31 of the edge strip-shaped part 1422 defines a first distance L1″ from a side of the second electrode extension part in the annular structure 222 facing towards the first side 31 of the edge strip-shaped part 1422, and the second side 32 of the edge strip-shaped part 1422 defines a second distance L2″ from a side of the second electrode extension part in the annular structure 222 facing towards the second side 32 of the edge strip-shaped part 1422. The first distance L1″ is greater than the second distance L2″, so as to improve the light-emitting efficiency and anti-static impact resistance of the LED chips, thereby enhancing the optoelectronic performance of LEDs.

### Embodiment 5

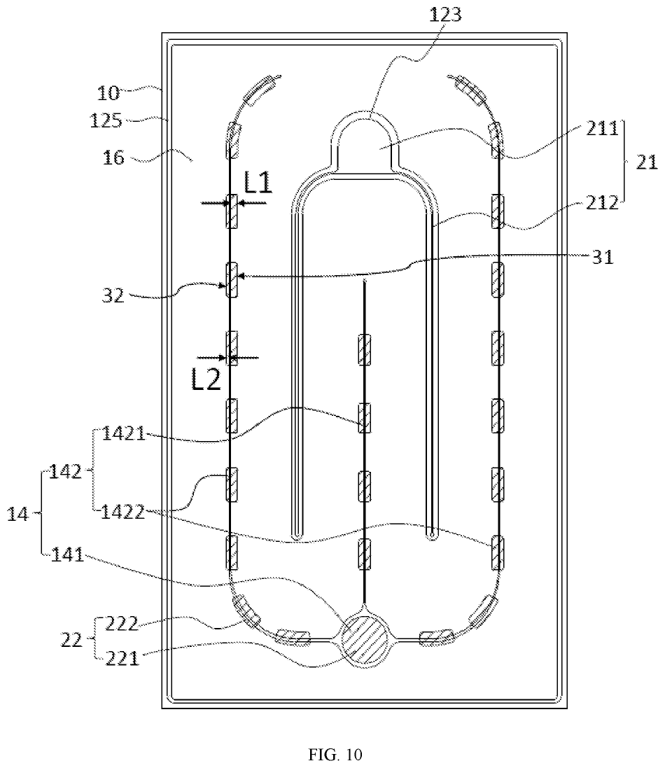

As shown in FIG. 10, which illustrates a top view of a LED according to the embodiment 5. Compared to the LED of the embodiment 1 in FIG. 1, the main differences of the LED of the embodiment 5 are as follows. In some embodiment, the current-blocking layer 14 includes strip-shaped parts 142 intermittently distributed. The transparent conducting layer 16 is connected to the second semiconductor layer 125 through intermittent parts between the strip-shaped parts 142 intermittently distributed, thereby increasing the contact area between the transparent conducting layer 16 and the second semiconductor layer 125 and improving the current expansion ability, so as to improve the light-emitting efficiency and anti-static impact ability of the LED chips, and thereby enhancing the optoelectronic performance of the LEDs.

### Embodiment 6

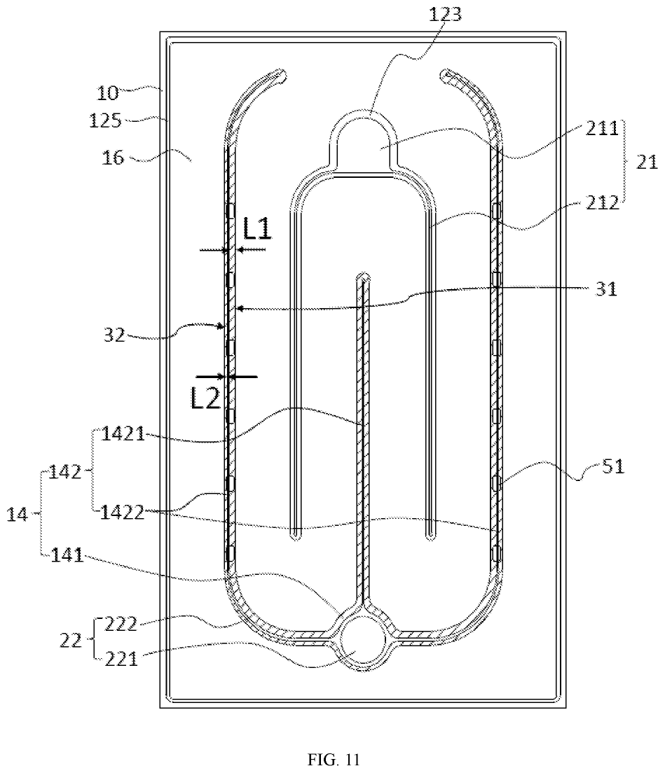

As shown in FIG. 11, which illustrates a top view of a LED according to the embodiment 6. Compared to the LED of the embodiment 1 in FIG. 1, the main differences of the LED of the embodiment 6 are as follows. In some embodiment, at least one opening 51 is defined on the strip-shaped part 142. The transparent conducting layer 16 is connected to the second semiconductor layer 125 through the opening 51 of the strip-shaped part 142, which increases the contact area between the transparent conducting layer 16 and the second semiconductor layer 125, thereby improving the current expansion ability and improving the light-emitting efficiency and anti-static impact ability of the LED chips, so as to improve the optoelectronic performance of the LEDs.

### Embodiment 7

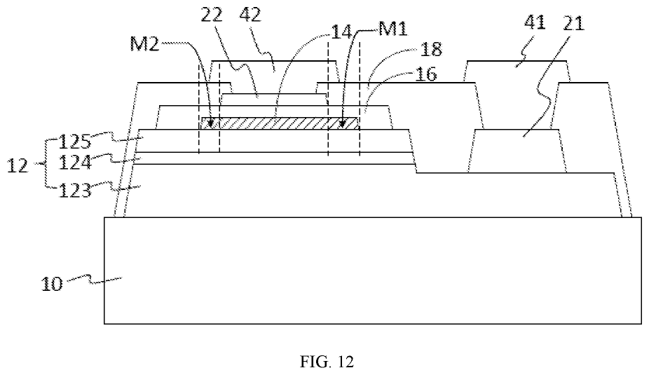

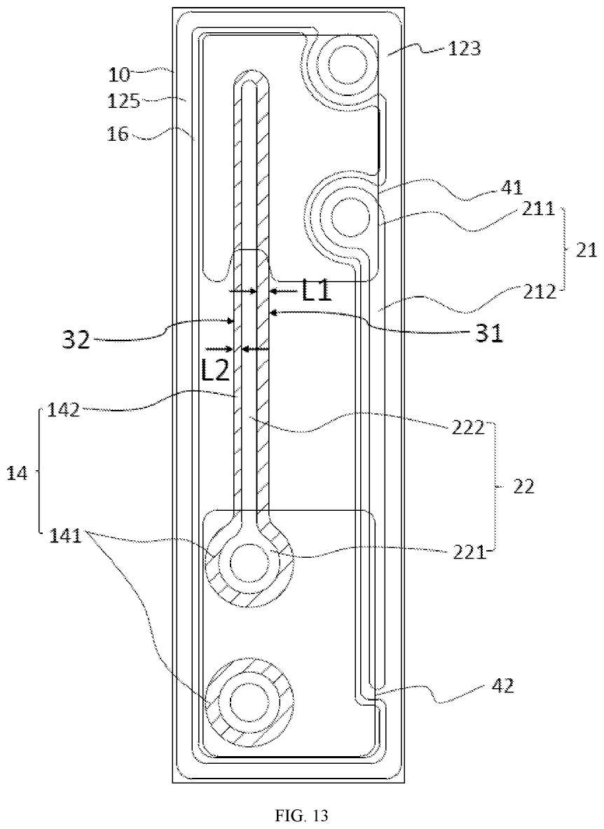

As shown in FIGS. 12 and 13, FIG. 12 illustrates a cross-sectional view of a LED according to the embodiment 7, and FIG. 13 illustrates a top view of a LED according to the embodiment 7. FIG. 12 is the schematic diagram of a longitudinal section taken along a F-F line of FIG. 13. Compared to the LED of the embodiment 1 in FIG. 1, the main differences of the LED of the embodiment 7 are as follows. The LED of this embodiment is in a flip-chip structure, which further includes a first bonding pad 41 and a second bonding pad 42. The first bonding pad 41 and the second bonding pad 42 are respectively connected to the first electrode 21 and the second electrode 22 through the openings of the insulating layer 18. However, the LED of the embodiment 1 is in a regular structure.

### Embodiment 8

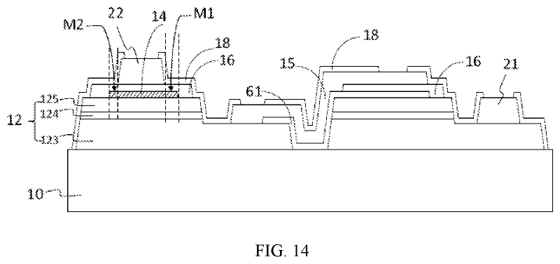

As shown in FIG. 14, which a cross-sectional view of a LED according to an embodiment 8 of the disclosure. The LEDs provided in the above embodiments are not only suitable for chips with regular structure and flip-chip structure as shown in FIG. 6 and FIG. 12, respectively, but also for chips with a high-voltage structure. As illustrated, the chip with the high-voltage structure includes multiple light-emitting unit, a substrate 10 and an insulating layer 18. Adjacent light-emitting units are isolated from each other through an isolation slot on the substrate 10, and electrically connected to each other via an interconnected electrode 15 that spans across the isolation slot. A second current-blocking layer 61 is disposed below the interconnected electrode 15 to achieve current blocking effect and avoid current accumulation phenomenon.

Furthermore, each light-emitting unit includes a semiconductor stacking layer 12, and the semiconductor stacking layer 12 includes a first semiconductor layer 123, a light-emitting layer 124, and a second semiconductor layer 125. Each light-emitting unit further includes a first electrode 21 electrically connected to the first semiconductor layer 123 or a second electrode 22 electrically connected to the second semiconductor layer 125. Specifically, the current-blocking layer 14 as described in the above embodiments is disposed below the second electrode 22. Its specific structure, performance, and advantages can refer to the above content, and will not be elaborated too much here.

A light-emitting device adopting the LED described in the above embodiments is further provided. The size of the LED can be Micro LED, Mini LED, or conventional LED. The LED can be applied to backlight displays or red-green-blue (RGB) display screens. The flip-chip LED with a small size can be integrated into the number of hundreds, thousands, or tens of thousands on application or packaging substrates to form the light source part of the backlight display device or RGB display device.

It should be noted that the effect is better when the length-width ratio of the LEDs in the above embodiments is greater than 1. This is because as the length-width ratio of the LED increases, the current expansion ability in the long side direction is poor. Therefore, the effect is more prominent when applied to the LEDs with larger length-width ratios. Specifically, in some embodiments, the length-width ratio of the LED is greater than 1.5. The LED in the above embodiments can be applied to various sizes, and the embodiments are not limited to this. However, the above embodiments have a more prominent effect when applied to large-sized LEDs. This is because large-sized LED chips have poor current expansion ability. The current-blocking layers with unequal distance expansion are disposed on two sides of the extended electrodes to allow current to be transmitted to the edge of the chip to a greater extent.

In addition, the LEDs in the above embodiments have better performance when applied in low current density scenarios. Because the utilization rate of the entire light-emitting area of the chip is relatively low at low current density. When the width of the current-blocking layer is large, the current near the electrode extension part can be greatly diffused around the chip, thereby maximizing the utilization of the light-emitting area. When the current density is high, the utilization rate of the entire light-emitting area of the chip is high. Although the current-blocking layer can allow the current to conduct more towards the edge of the chip, the light-emitting area at the bottom of the current-blocking layer cannot be effectively utilized, thereby resulting in a decrease in the overall light-emitting effect.

It should be noted that due to differences in photoresists and other factors, the lines described in the disclosure may not necessarily be completely straight, and may also include situations where the straight edges may slightly bulge or bend during production. The arc described in the disclosure is not necessarily an arc on a circle, but also includes situations where the arc edge may slightly bulge or bend during production.

In summary, embodiments of the disclosure provide the LEDs and the light-emitting device. By providing current-blocking layers with unequal distance expansion on both sides of the same extended electrodes, or disposing current-blocking layers with different widths and distances on the extended electrodes in different areas of the chip, the position of current accumulation can be controlled to achieve local current regulation effect, thereby avoiding the phenomenon of relatively concentrated current density in certain areas. Therefore, the LED of the disclosure has good light-emitting efficiency and achieves the effect of improving anti-static impact ability, and further enhancing the photoelectric performance of the LEDs.

In addition, those skilled in the art should understand that although there are many problems in the related art, each embodiment or technical solution of the disclosure can be improved in only one or a few aspects, without having to simultaneously solve all the technical problems listed in the related art or the background. Those skilled in the art should understand that any content not mentioned in a claim should not be used as a limitation on that claim.

Finally, it should be noted that the above embodiments are only used to illustrate the technical solution of the disclosure, and not to limit it. Although the disclosure has been described in detail with reference to the embodiments, those skilled in the art should understand that they can still modify the technical solutions recorded in the embodiments, or equivalently replace some or all of the technical features thereof. And these modifications or replacements do not make the essence of the corresponding technical solutions deviate from the scope of the technical solutions of the various embodiments of the disclosure.

What is claimed is:

1. A light-emitting diode, comprising:
a semiconductor stacking layer, wherein the semiconductor stacking layer comprises: a first semiconductor layer, a light-emitting layer and a second semiconductor layer, and the light-emitting layer is disposed between the first semiconductor layer and the second semiconductor layer;
a current-blocking layer, wherein the current-blocking layer is disposed on the second semiconductor layer and comprises: at least one strip-shaped part;
a transparent conducting layer, wherein the transparent conducting layer is disposed on the second semiconductor layer and covers the current-blocking layer;
a first electrode, wherein the first electrode is disposed on the first semiconductor layer; and
a second electrode, wherein the second electrode is disposed on the transparent conducting layer and comprises: a pad and at least one extension part, the pad of the second electrode is connected to the at least one extension part of the second electrode, and the at least one extension part of the second electrode is disposed on the at least one strip-shaped part;
wherein as viewed from a top of the light-emitting diode towards the semiconductor stacking layer, each of the at least one strip-shaped part comprises: a first side and a second side; the first side of each strip-shaped part defines a first distance from a side of a respective one of the at least one extension part of the second electrode facing towards the first side, and the second side of each strip-shaped part defines a second distance from a side of the respective extension part of the second electrode facing towards the second side; the first distance of one of the at least one strip-shaped part is greater than the second distance of the one of the at least one strip-shaped part.

2. The light-emitting diode as claimed in claim 1, wherein the first distance of the one of the at least one strip-shaped part is a shortest distance of the first side of the one of the at least one strip-shaped part from the side of the respective extension part of the second electrode facing towards the first side, and the second distance of the one of the at least one strip-shaped part is a shortest distance of the second side of the one of the at least one strip-shaped part from the side of the respective extension part of the second electrode facing towards the second side.

3. The light-emitting diode as claimed in claim 1, wherein a width of each of the at least one strip-shaped part is greater than a width of the respective extension part of the second electrode.

4. The light-emitting diode as claimed in claim 1, wherein in a top view, a projection of each of the at least one extension part of the second electrode is within the respective strip-shaped part.

5. The light-emitting diode as claimed in claim 1, wherein the first distance of each strip-shaped part is in a range of 1-15 micrometers (μm), the second distance of each strip-shaped part is in a range of 1-15 μm, and the first distance is in a range of 0.5-5 μm longer than the second distance in the one of the at least one strip-shaped part.

6. The light-emitting diode as claimed in claim 5, wherein in the one of the at least one strip-shaped part, the second distance is in a range of ¼-¾ to the first distance.

7. The light-emitting diode as claimed in claim 1, wherein a number of the at least one strip-shaped part is same as a number of the at least one extension part of the second electrode.

8. The light-emitting diode as claimed in claim 1, wherein as viewed from the top of the light-emitting diode towards the semiconductor stacking layer, the first side of the one of the at least one strip-shaped part is closer to the first electrode than the second side of the one of the at least one strip-shaped part.

9. The light-emitting diode as claimed in claim 1, wherein as viewed from the top of the light-emitting diode towards the semiconductor stacking layer, the at least one strip-shaped part comprises: a central strip-shaped part and a plurality of edge strip-shaped parts; a first side is closer to the central strip-shaped part than a second side in each of the plurality of edge strip-shaped parts; and a first distance is equal to a second distance in the central strip-shaped part, and a first distance is greater than a second distance in each edge strip-shaped part.

10. The light-emitting diode as claimed in claim 9, wherein the first distance is in a range of 0.5-5 μm longer than the second distance in each edge strip-shaped part, and the second distance is in a range of ¼-¾ to the first distance in each edge strip-shaped part.

11. The light-emitting diode as claimed in claim 1, wherein the current-blocking layer is made of an insulating material capable of transmitting at least partial light, and a thickness of the current-blocking layer is in a range of 50 nanometers (nm) to 500 nm.

12. The light-emitting diode as claimed in claim 1, wherein the first electrode comprises: a pad and an extension part, the pad of the first electrode is connected to the extension part of the first electrode, the extension part of the first electrode extends from the pad of the first electrode towards the second electrode, and the at least one extension part of the second electrode extends from the pad of the second electrode towards the pad of the first electrode.

13. The light-emitting diode as claimed in claim 12, wherein the at least one extension part of the second electrode is in a strip-shaped structure or an annular structure, and the at least one strip-shaped part is in a strip-shaped structure or an annular structure corresponding to the at least one extension part of the second electrode.

14. The light-emitting diode as claimed in claim 1, wherein the at least one strip-shaped part of the current-blocking layer comprises: a strip-shaped part continuously distributed or strip-shaped parts intermittently distributed.

15. The light-emitting diode as claimed in claim 14, wherein at least one opening is defined on the at least one strip-shaped part, and the transparent conducting layer is connected to the second semiconductor layer through the at least one opening.

16. The light-emitting diode as claimed in claim 1, wherein a ratio of a length of the light-emitting diode to a width of the light-emitting diode is greater than 1.

17. A light-emitting diode, comprising:
a semiconductor stacking layer, wherein the semiconductor stacking layer comprises: a first semiconductor layer, a light-emitting layer and a second semiconductor layer, the light-emitting layer is disposed between the first semiconductor layer and the second semiconductor layer;
a current-blocking layer, wherein the current-blocking layer is disposed on the second semiconductor layer and comprises: at least one strip-shaped part;
a transparent conducting layer, wherein the transparent conducting layer is disposed on the second semiconductor layer and covers the current-blocking layer;
a first electrode, wherein the first electrode is disposed on the first semiconductor layer;
a second electrode, wherein the second electrode is disposed on the transparent conducting layer and comprises: a pad and at least one extension part, the pad of the second electrode is connected to the at least one extension part of the second electrode, and the at least one extension part of the second electrode is disposed on the at least one strip-shaped part;
wherein as viewed from a cross-sectional view where the at least one strip-shaped part is located, a projection of one of the at least one strip-shaped part of the current-blocking layer on the second semiconductor layer defines two mesas of a first mesa and a second mesa non-overlapped with the at least one extension part of the second electrode; a projection of the first mesa and a projection of the second mesa on the second semiconductor layer are located on different sides of the one of the at least one strip-shaped part of the current-blocking layer, respectively, and the first mesa is greater than the second mesa.

18. The light-emitting diode as claimed in claim 17, wherein the second mesa is in a range of ¼-¾ to the first mesa.

19. The light-emitting diode as claimed in claim 17, wherein the first mesa is closer to the first electrode than the second mesa.

20. A light-emitting device, adopting the light-emitting diode as claimed in claim 1.
